(19) United States
(12) Patent Application Publication
(10) Pub. No.: US 2025/0233061 A1
(43) Pub. Date: Jul. 17, 2025

(54) Interposer

(71) Applicants: TE Connectivity Japan G. K., Kawasaki-shi (JP); TE Connectivity Solutions GmbH, Schaffhausen (CH)

(72) Inventors: Shinichi Hashimoto, Kawasaki-shi (JP); Hiroshi Shirai, Kawasaki-shi (JP); Hirotate Kadobayashi, Kawasaki-shi (JP); Chad William Morgan, Middletown, PA (US)

(73) Assignees: TE Connectivity Japan G. K., Kawasaki-shi (JP); TE Connectivity Solutions GmbH, Schaffhausen (CH)

(21) Appl. No.: 19/029,152

(22) Filed: Jan. 17, 2025

(30) Foreign Application Priority Data
Jan. 17, 2024 (JP) 2024-005537

(51) Int. Cl. H01L 23/498

(52) U.S. Cl. CPC H01L 23/49827; H01L 23/49838

(57) ABSTRACT

An interposer includes a housing and a signal contact pair. The housing has a plurality of through holes extending between a first face and a second face of the housing. The signal contact pair includes two signal contacts, each having a base portion press-fitted into the through hole, a first signal contact beam extending toward the first face from the base portion and having a first contact portion, and a second signal contact beam extending toward the second face from the base portion and having a second contact portion. A part of the first and/or second contact beam in one of the signal contacts has a protruding portion located further outside the through hole than the first and/or second face and protruding toward the other signal contact.

### CROSS-REFERENCE TO RELATED APPLICATION

This application claims the benefit of Japanese Patent Application No. 2024-005537 filed on Jan. 17, 2024, the whole disclosure of which is incorporated herein by reference.

### FIELD OF THE DISCLOSURE

The disclosure relates to an interposer.

### BACKGROUND OF THE INVENTION

In the prior art, an interposer may be provided between two electronic components to electrically connect the electronic components to each other. This interposer includes a housing having a plurality of through holes and a plurality of contacts respectively inserted into and retained in the through holes. The contacts included in the interposer each comprise a base portion positioned in the through hole of the housing and retained in the housing and two contact beams respectively extending to two main faces of the housing from the base portion. The plurality of contacts can include a signal contact pair including the two signal contacts positioned to be adjacent to each other in their width direction and handling signal transmission.

Interposers according to the prior art, however, do not achieve desired electrical characteristics and/or electrical performance.

### SUMMARY OF THE INVENTION

According to an embodiment of the present disclosure, an interposer comprises a housing and a signal contact pair. The housing includes a housing body portion having a first face directed toward a side of a first electronic component, and a second face directed toward a side of a second electronic component. A plurality of through holes extend through the housing body between the first face and the second face. The signal contact pair includes two signal contacts, each of which includes a base portion press-fitted into the through hole, a first signal contact beam extending toward the first face from the base portion and having a first contact portion contacting the first electrical component in its distal end portion, a second signal contact beam extending toward the second face from the base portion and having a second contact portion contacting the second electrical component in its distal end portion, adjacent to each other with a predetermined spacing in a width direction of the signal contacts. At least one of a part of the first contact beam in one of the signal contacts has a first protruding portion located further outside the through hole than the first face and protruding toward the other signal contact, and a part of the second contact beam in the other signal contact has a second protruding portion located further outside the through hole than the second face and protruding toward the one signal contact.

### DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1A is an isometric view schematically illustrating an interposer according to the disclosure.

FIG. 1B is an isometric view schematically illustrating the interposer according to the disclosure that can be electrically connected to two electronic components.

FIG. 2 is a partially enlarged isometric view schematically illustrating the interposer according to the disclosure in a part surrounded by a dotted line in FIG. 1A.

FIG. 3 is a partially enlarged sectional view schematically illustrating the interposer according to the disclosure in the part surrounded by the dotted line viewed along a line A-A in FIG. 2.

FIG. 4 is an isometric view schematically illustrating an example of a contact including signal contacts having a characteristic configuration in the interposer according to the disclosure.

FIG. 5 is an isometric view schematically illustrating another example of a contact including signal contacts having a characteristic configuration in the interposer according to the disclosure.

FIG. 6 is an isometric view schematically illustrating another example of a contact including signal contacts having a characteristic configuration in the interposer according to the disclosure.

FIG. 7 is an isometric view schematically illustrating another example of a contact including signal contacts having a characteristic configuration in the interposer according to the disclosure.

FIG. 8 is an isometric view schematically illustrating another example of a contact including signal contacts having a characteristic configuration in the interposer according to the disclosure.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An interposer according to the disclosure will be described below. More specifically, an overall configuration of the interposer according to the disclosure will be described, followed by a description of the characteristic part of the disclosure.

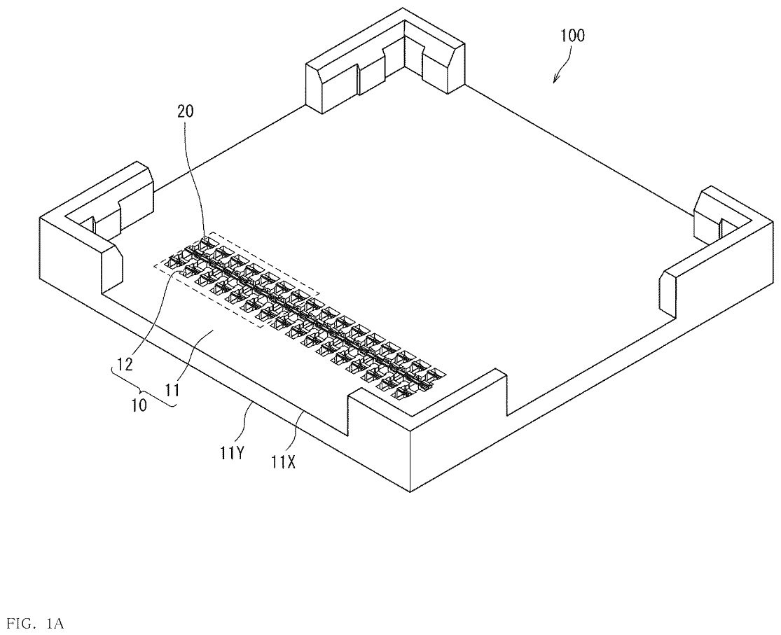

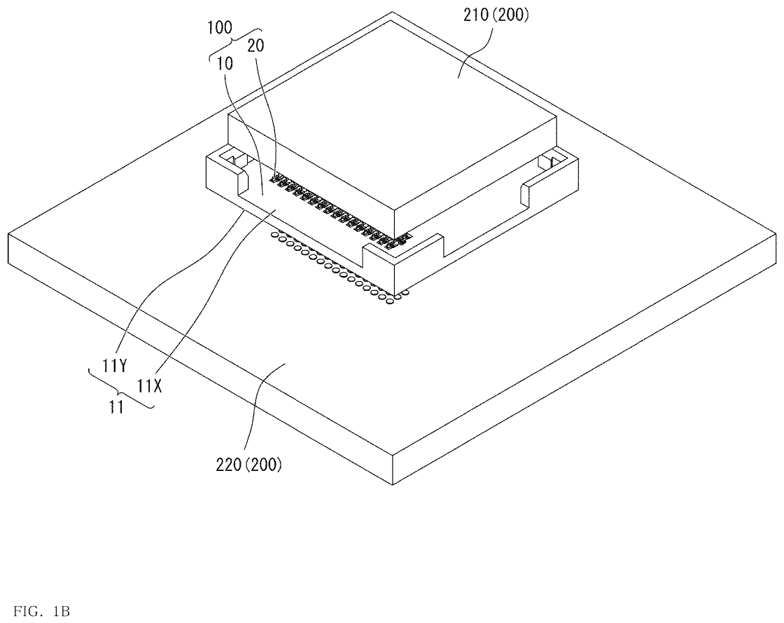

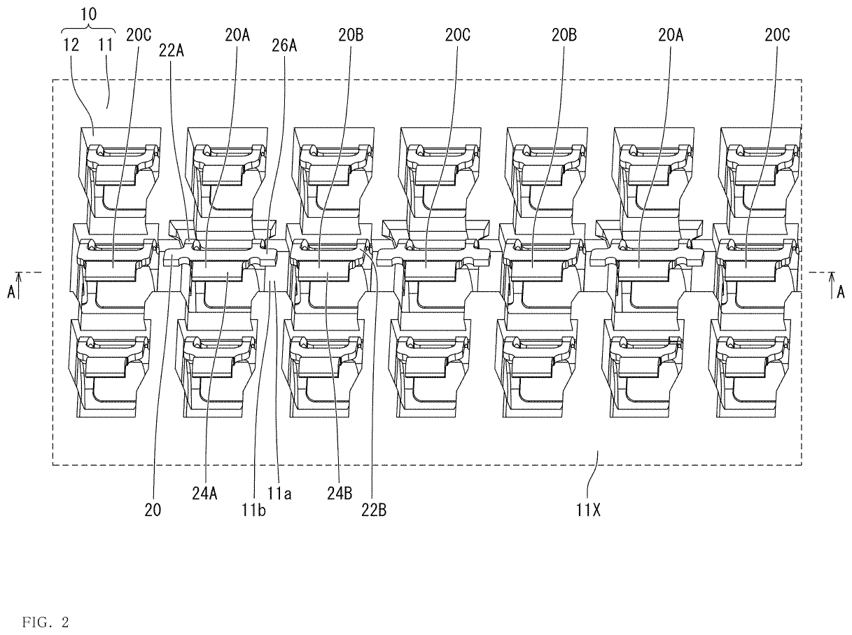

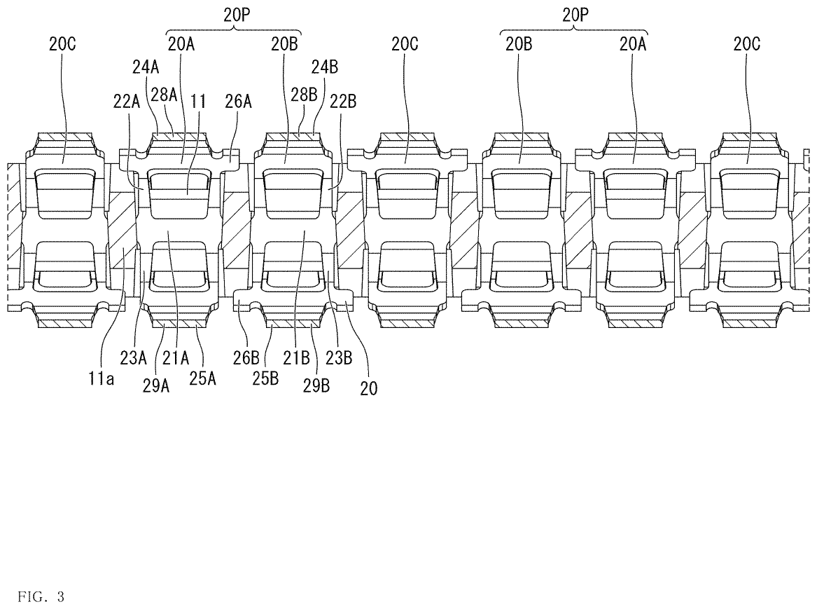

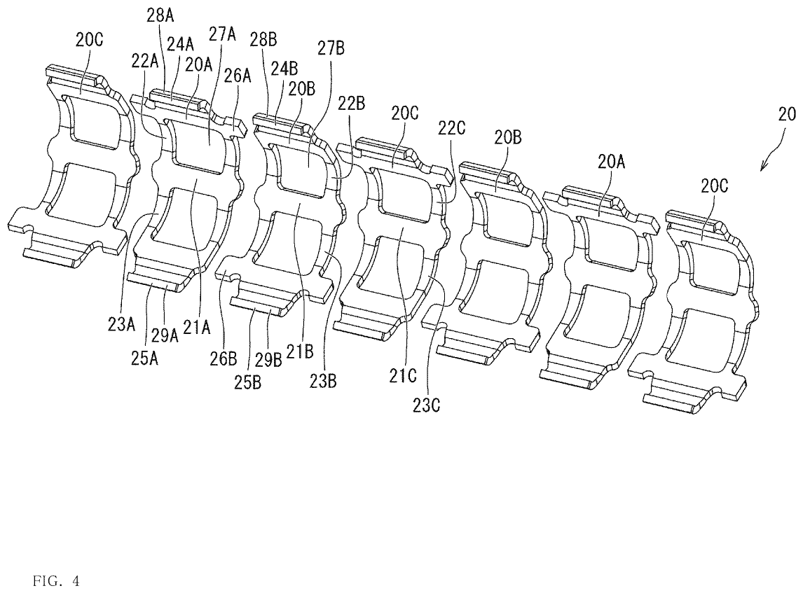

FIG. 1A is an isometric view schematically illustrating an interposer according to the disclosure. FIG. 2 is a partially enlarged isometric view schematically illustrating the interposer according to the disclosure in a part surrounded by a dotted line in FIG. 1A. FIG. 3 is a partially enlarged sectional view schematically illustrating the interposer according to the disclosure in the part surrounded by the dotted line viewed along a line A-A in FIG. 2. FIG. 4 is an isometric view schematically illustrating an example of a contact including signal contacts having a characteristic configuration in the interposer according to the disclosure.

As illustrated in FIG. 1A, an interposer 100 according to the disclosure roughly includes a housing 10 and a plurality of contacts 20. The housing 10 includes a housing body portion 11 having two main faces (a first face 11X and a second face 11Y) corresponding to each other and a plurality of through holes 12 that penetrate therethrough between the two main faces (the first face 11X and the second face 11Y). The above-described first face 11X can be a face directed toward the side of a first electronic component 210 out of two electronic components 200. The second face 11Y can be a face directed toward the side of a second electronic component 220 out of the two electronic components 200 (See FIG. 1B).

Although not particularly limited, examples of the above-described first electronic component 210 can include an integrated circuit (IC). Examples of the above-described second electronic component 220 can include a circuit board. In this case, the interposer 100 according to the disclosure functions to mediate signal transmission between the circuit board and the IC.

An aspect in which the plurality of through holes 12 are provided in a lattice shape in a local part of the housing body portion 11 is illustrated as an example in FIG. 1A, but without having to be limited to this, the plurality of through holes 12 may be provided in a lattice shape for a large part of the housing body portion 11. A material forming the housing 10 may be a material having an insulation property. For example, a thermoplastic resin material can be selected.

As illustrated in FIGS. 2 to 4, the plurality of contacts 20 include signal contacts for transmitting a signal (or also referred to as signal contacts) and ground contacts 20C for grounding (or also referred to as ground contacts). A material forming the contact 20 may be a metal material having an electric conductivity, for example, copper.

The above-described signal contacts include a first signal contact 20A and a second signal contact 20B that can be the same in shape while being opposite in positioning direction. The first signal contact 20A and the second signal contact 20B are adjoined (i.e., paired) with a predetermined spacing in a width direction of the signal contacts to compose a signal contact pair 20P.

The ground contacts 20C can be positioned between the signal contact pairs 20P adjacent to each other and outside the signal contact pairs 20P in consideration of electrical characteristics of the interposer 100 according to the disclosure. That is, the ground contacts 20C can be positioned on both sides of each of the signal contact pairs 20P.

Although described below, the ground contact 20C may have the same shape as that of the first signal contact 20A and the second signal contact 20B or may have a different shape from that of the first signal contact 20A and the second signal contact 20B, as illustrated in FIGS. 2 to 4.

When the contacts are described in the description and drawings, “A” is suffixed to components of the first signal contact, “B” is suffixed to components of the second signal contact, and “C” is suffixed to components of the ground contact.

The first signal contact 20A and the second signal contact 20B can be respectively positioned in the through holes 12 adjacent to each other in the contact width direction among the plurality of through holes 12 in the above-described housing 10. The ground contacts 20C can be respectively positioned in the through holes 12 located on both sides of the signal contact pair 20P among the plurality of through holes 12 in the housing 10.

Each of the plurality of contacts 20 including the signal contacts and the ground contacts 20C has a base portion that can be press-fitted into the above-described through hole 12. Such press-fitting allows the signal contact to be retained in the through hole 12 by cutting into an inner wall face of the through hole 12 when the signal contact is press-fitted into the through hole 12.

In addition, each of the plurality of contacts 20 can include a first contact beam extending more outward than the first face 11X of the housing 10 from the base portion and having a first contact portion in its distal end portion. Further, each of the plurality of contacts 20 can include a second contact beam extending more outward than the second face of the housing 10 from the above-described base portion and having a second contact portion in its distal end portion.

If the above-described first electronic component 210 is an IC, a connection pad formed at a location corresponding to each of the signal contacts and for transmitting a signal is provided on a face, directed toward the first face 11X side of the housing 10, of the IC. When the IC is mounted, the first contact portion in each of the signal contacts can electrically contact the connection pad.

If the above-described second electronic component 220 is a circuit board, a connection pad formed at a location corresponding to each of the signal contacts and for transmitting a signal is provided on a face, directed toward the second face 11Y side of the housing 10, of the circuit board. When the interposer 100 according to the disclosure is mounted on the circuit board, the second contact portion in each of the signal contacts electrically contacts the connection pad on the circuit board.

As for the first signal contact 20A, the first signal contact 20A includes a base portion 21A, a first signal contact beam 22A, and a second signal contact beam 23A, as illustrated in FIGS. 2 to 4. The first signal contact 20A has two openings 27A respectively including the base portion 21A and the signal contact beams 22A and 23A. This opening 27A is a spatial region surrounded by the base portion 21A and each of the signal contact beams continuous therewith.

The first signal contact beam 22A extends more outward than the first face 11X of the housing 10 (also see FIG. 1A) from the base portion 21A and has a first contact portion 24A, described above, in a distal end portion 28A. The second signal contact beam 23A extends more outward than the second face (corresponding to 11Y in FIG. 1A) of the housing 10 from the above-described base portion 21A and has a second contact portion 25A, described above, in a distal end portion 29A.

Similarly, as for the second signal contact 20B, the second signal contact 20B includes a base portion 21B, a first signal contact beam 22B, and a second signal contact beam 23B, as illustrated in FIGS. 2 to 4. The second signal contact 20B has two openings 27B respectively including the base portion 21B and the signal contact beams 22B and 23B. This opening 27B is a spatial region surrounded by the base portion 21B and each of the signal contact beams continuous therewith. The first signal contact beam 22B extends more outward than the first face 11X of the housing 10 (also see FIG. 1A) from the base portion 21B and has a first contact portion 24B, described above, in a distal end portion 28B. The second signal contact beam 23B extends more outward than the second face (corresponding to 11Y in FIG. 1A) of the housing 10 from the above-described base portion 21B and has a second contact portion 25B, described above, in a distal end portion 29B.

In each of the signal contacts 20A and 20B, the openings are present, whereby the signal contact, in particular the signal contact beams, can have an elastic function. When the signal contact has such an elastic function, a contact region of the above-described signal contact with the electronic component 200 can be made larger than that when it does not have an elastic function. Specifically, a contact region between the contact portion of the above-described signal contact beam and the above-described connection pad can be made large. Thus, a favorable contact between the electronic component 200 and the signal contact is ensured, thereby allowing an electrical connection therebetween to be favorably ensured. Each of the contacts 20A and 20B may be non-planar, in the illustrated embodiment, may be arcuate or curved between its contact portions.

As described above, a characteristic part of the disclosure will be described below after an overall configuration of the interposer 100 according to the disclosure is described.

The interposer 100 according to the disclosure is characterized by a configuration of the contact 20 as its constituent element, in particular the signal contact. Specifically, in the disclosure, in the first signal contact 20A and the second signal contact 20B, which are adjacent to each other, a part of the first contact beam in one of the signal contacts has a first protruding portion located more outside the through hole than the first face 11X of the above-described housing 10 and protruding toward the adjacent other signal contact in the contact width direction.

In addition or alternatively, in the disclosure, a part of the second contact beam in the other of the first signal contact 20A and the second signal contact 20B, which are adjacent to each other, has a second protruding portion located more outside the through hole 12 than the second face 11Y of the above-described housing 10 and protruding toward the one signal contact in the contact width direction.

In an example illustrated in FIGS. 2 to 4, the first contact beam 22A in the first signal contact 20A can have a first protruding portion 26A located outside the first face 11X of the above-described housing 10 and protruding toward the adjacent second signal contact 20B in the contact width direction. Further, the second contact beam 23B in the second signal contact 20B can have a second protruding portion 26B located outside the second face 11Y of the housing 10 and protruding toward the adjacent first signal contact 20A in the contact width direction.

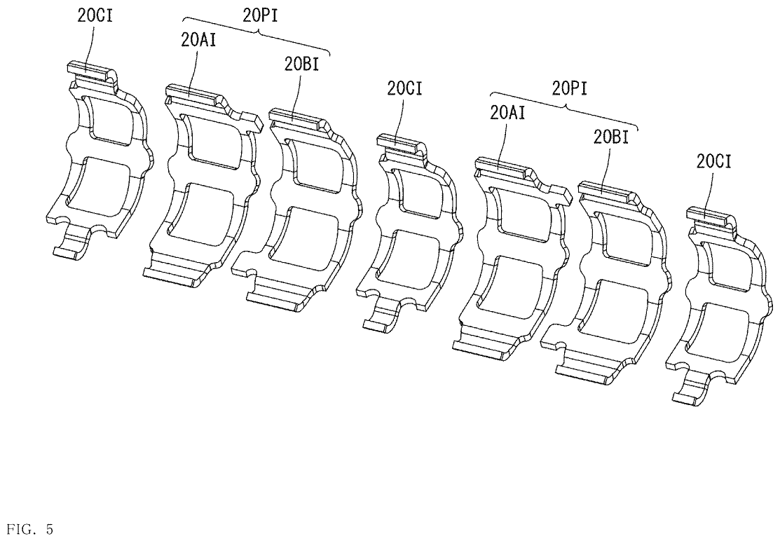

In the example illustrated in FIGS. 2 to 4, each of the above-described protruding portions 26A and 26B can be positioned not only to protrude toward the adjacent signal contact but also to protrude toward the adjacent ground contact 20C. Without having to be limited to this, each of the protruding portions 26A and 26B can be positioned to protrude toward the adjacent signal contact, while they may be positioned not to protrude toward the adjacent ground contact 20C, as illustrated in FIGS. 5 to 7.

By at least one of the first protruding portion 26A and the second protruding portion 26B, a desired spacing between the signal contacts adjacent to each other, specifically between the first signal contact beams and/or between the second signal contact beams can be adjusted. This makes it possible to further improve the electrical characteristics of the interposer 100 according to the disclosure.

Further, by each of the above-described protruding portions 26A and 26B, the electrical characteristics of the interposer 100 can be further improved, thereby also making it possible to more reduce the number of signal contacts positioned in the contact width direction in a housing of a predetermined size, that is, the number of contacts to be used than that when the protruding portion is not provided in the signal contact. That is, the electrical characteristics of the interposer 100 can be favorably ensured even if the number of signal contacts is more reduced than that when the protruding portion is not provided in the signal contact.

In an example, the presence of the first protruding portion 26A and the second protruding portion 26B makes it possible to make a minimum spacing between first contact beams in adjacent signal contacts and a minimum spacing between second contact beams in the adjacent signal contacts smaller than a minimum spacing between base portions in the adjacent signal contacts. As another example, respective central axis lines between first contact beams and between second contact beams in adjacent signal contacts can be positioned while being shifted from a central axis line between base portions in the adjacent signal contacts. The above-described adjustment can be made, thereby making it possible to further improve the electrical characteristics of the interposer 100 according to the disclosure.

As illustrated in FIGS. 2 and 3, in the disclosure, a wall portion 11a of the housing body portion 11 can be located between the adjacent two signal contacts. The wall portion 11a makes it possible to position the two signal contacts away from each other, and the wall portion 11a itself contributes to an improvement in the electrical characteristics of the interposer 100. When the above-described wall portion 11a is provided between the two signal contacts, each of the base portions in the adjacent signal contacts are press-fitted into and brought into contact with an inner wall face of the wall portion 11a. On the other hand, at least one of the above-described first protruding portion 26A and second protruding portion 26B can have a configuration in which it extends from the through hole 12 side of the housing 10 to the upper side of the wall portion 11a. In other words, the wall portion 11a between the two signal contacts can be located below at least one of the first protruding portion 26A and second protruding portion 26B. That is, the wall portion 11a between the two signal contacts and at least one of the first protruding portion 26A and the second protruding portion 26A can be positioned to overlap each other. This makes it possible to adjust a desired spacing between the first signal contact beams and/or between the second signal contact beams and as a result to make it possible to further improve the electrical characteristics of the interposer 100.

Further, if the ground contact 20C has the same shape as that of the first signal contact 20A and the second signal contact 20B as illustrated in FIGS. 2 to 4, as described above, the ground contact 20C can also preferably include a protruding portion protruding toward the adjacent signal contact from the viewpoint of a further improvement in the electrical characteristics of the interposer 100.

In the disclosure, at least a configuration in which the above-described wall portion 11a between the two signal contacts is more recessed than a portion, other than the wall portion 11a, of the housing body portion 11 can be adopted. In other words, at least one of the first face 11X and the second face 11Y of the housing body portion 11 (see FIG. 1A) in the wall portion 11a of the housing body portion 11 between the two signal contacts can have a recessed region (see FIG. 2).

According to such a configuration, the above-described protruding portions 26A and 26B can be more favorably housed in the recessed region 11b than when the first face 11X and the second face 11Y of the housing body portion 11 have a substantially flat shape as a whole. This makes it possible to reduce the size of the interposer 100 according to the disclosure.

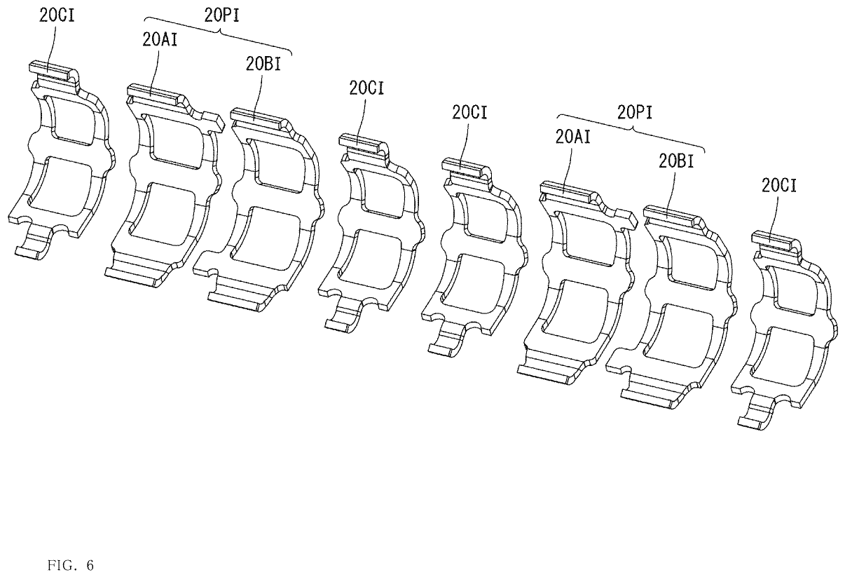

The ground contact will be described below. The ground contact 20C can have the same shape as that of the first signal contact 20A and the second signal contact 20B, as illustrated in FIGS. 2 to 4, in an example. In another example, a ground contact 20CI may have a different shape from that of the first signal contact 20A and the second signal contact 20B, as illustrated in FIG. 5. In still another example, two or more ground contacts located between signal contact pairs 20P may be positioned in consideration of an improvement in the electrical characteristics of the interposer 100 according to the disclosure, as illustrated in FIG. 6.

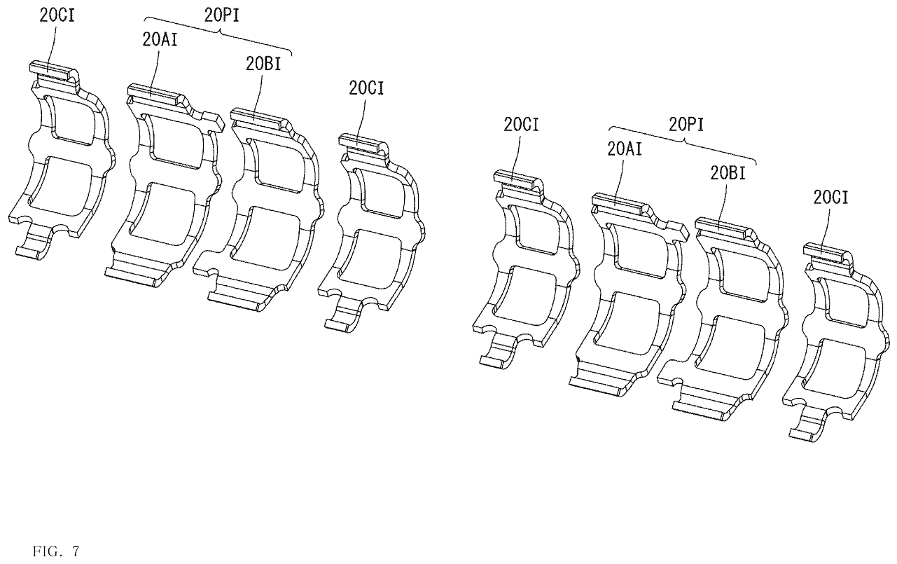

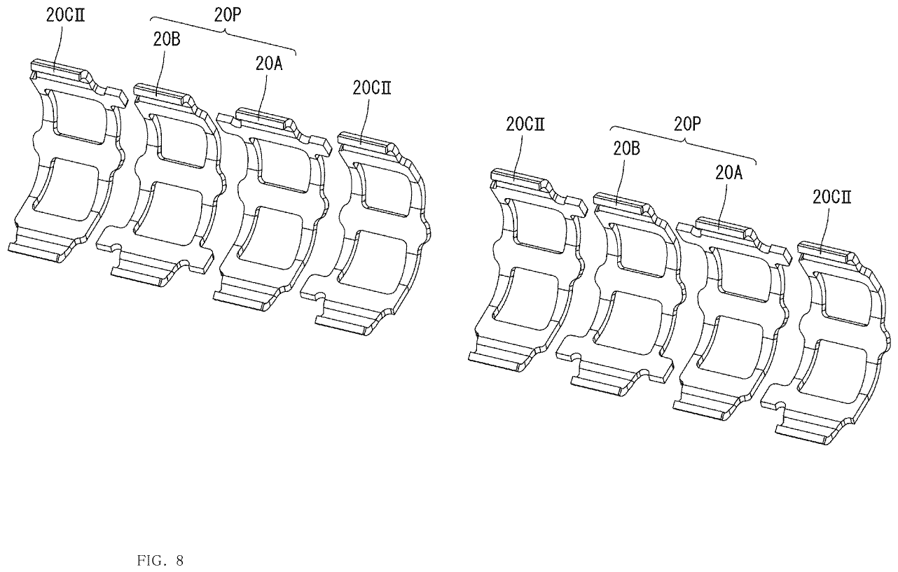

As another example of FIGS. 6, if two ground contacts, for example, are positioned between signal contact pairs 20P, as illustrated in FIGS. 7 and 8, a spacing between the two ground contacts in the contact width direction may be made larger in consideration of an improvement in the electrical characteristics of the interposer 100 according to the disclosure.

The interposer 100 according to the disclosure is not limited to that in the above-described embodiment. Changes may be made, as needed, within the scope of the disclosure.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

1. An interposer, comprising:
a housing including a housing body portion having a first face arranged to oppose a side of a first electronic component, a second face arranged to oppose a side of a second electronic component, and a plurality of through holes extending between the first face and the second face; and
a signal contact pair including two signal contacts, each including:
a base portion press-fitted into a respective one of the plurality of through holes;
a first signal contact beam extending toward the first face from the base portion and having a first contact portion for contacting the first electrical component in its distal end portion; and
a second signal contact beam extending toward the second face from the base portion and having a second contact portion for contacting the second electrical component in its distal end portion, the signal contacts adjacent to each other with a predetermined spacing in a width direction of the signal contacts, wherein at least one of:
a part of the first contact beam in one of the signal contacts has a first protruding portion located further outside the through hole than the first face and protruding toward the other signal contact; and
a part of the second contact beam in the other signal contact has a second protruding portion located further outside the through hole than the second face and protruding toward the one signal contact.

2. The interposer according to claim 1, wherein a wall portion of the housing body portion is located between the adjacent two signal contacts.

3. The interposer according to claim 2, wherein at least one of the first protruding portion and the second protruding portion extends toward an upper side of the wall portion from a side of the through hole of the housing.

4. The interposer according to claim 2, wherein the wall portion is located below at least one of the first protruding portion and the second protruding portion.

5. The interposer according to claim 2, wherein at least the wall portion is further recessed than a portion, other than the wall portion, of the housing body portion.

6. The interposer according to claim 2, wherein at least one of the first face and the second face of the housing body portion in the wall portion of the housing body portion between the two signal contacts has a recessed region.

7. The interposer according to claim 6, wherein at least one of the first protruding portion and the second protruding portion is housed in the recessed region.

8. The interposer according to claim 2, wherein the wall portion between the two signal contacts and at least one of the first protruding portion and the second protruding portion overlap each other.

9. The interposer according to claim 1, further comprising ground contacts respectively positioned on each side of the signal contact pair.

10. The interposer according to claim 9, wherein the ground contact has the same shape as that of the signal contact.

11. The interposer according to claim 9, wherein the protruding portion of the signal contact protrudes toward the adjacent ground contact.

12. An interposer, comprising:
a housing defining a first side, a second side, and a plurality of through holes extending between the first side and the second side; and
a signal contact pair including two signal contacts, each signal contact having:
a base portion fitted into a respect one of the plurality through holes;
a first signal contact beam extending toward the first side from the base portion and having a first contact portion adapted to contact a first electrical component; and
a second signal contact beam extending toward the second side from the base portion and having a second contact portion adapted to contact a second electrical component, the two signal contacts adjacent to each other with a predetermined spacing in a width direction of the signal contacts, wherein the first contact beam in one of the signal contacts has a first protruding portion located further outside the through hole than the first side and protruding toward the other signal contact.

13. The interposer according to claim 12, wherein a part of the second contact beam in the other signal contact has a second protruding portion located further outside the through hole than the second side and protruding toward the one signal contact.

14. The interposer according to claim 13, wherein a wall portion of the housing is located between the adjacent two signal contacts.

15. The interposer according to claim 14, wherein at least one of the first protruding portion and the second protruding portion extends toward an upper side of the wall portion from a side of the through hole of the housing.

16. The interposer according to claim 14, wherein the wall portion is located below at least one of the first protruding portion and the second protruding portion.

17. The interposer according to claim 14, wherein at least one of the first side and the second side of the housing in the wall portion of the between the two signal contacts has a recessed region.

18. The interposer according to claim 16, wherein at least one of the first protruding portion and the second protruding portion is housed in the recessed region.

19. The interposer according to claim 12, further comprising ground contacts respectively positioned on each side of the signal contact pair.

20. An assembly, comprising:
a first electrical component;
a second electrical component; and
an interposer arranged between and electrically connecting the first electrical component to the second electrical component, the interposer including:
a housing having a first face directed toward a side of the first electronic component, a second face directed toward a side of the second electronic component, and a plurality of through extending between the first face and the second face; and
a signal contact pair including two signal contacts, each signal contact including:
a base portion press-fitted into a respective one of the plurality of through holes;
a first signal contact beam extending toward the first face from the base portion and having a first contact portion contacting the first electrical component; and
a second signal contact beam extending toward the second face from the base portion and having a second contact portion contacting the second electrical component, the signal contacts adjacent to each other with a predetermined spacing in a width direction of the signal contacts, wherein at least one of:
a part of the first contact beam in one of the signal contacts has a first protruding portion located further outside the through hole than the first face and protruding toward the other signal contact; and
a part of the second contact beam in the other signal contact has a second protruding portion located further outside the through hole than the second face and protruding toward the one signal contact.
